(19) United States
(12) Patent Application Publication
(10) Pub. No.: US 2008/0186689 A1
(43) Pub. Date: Aug. 7, 2008

(54) ELECTRONIC EQUIPMENT

(75) Inventor: Takamichi Koizumi, Akiruno-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: TEAC CORPORATION, Tokyo (JP)

(21) Appl. No.: 12/023,955

(22) Filed: Jan. 31, 2008

(30) Foreign Application Priority Data
Feb. 5, 2007 (JP) 2007-025260

(51) Int. Cl. H05K 5/00

(52) U.S. Cl. 361/752

(57) ABSTRACT

A housing of a controller serving as electronic equipment is made up of an upper case and a lower case that are formed from a resin and fitted together. An accommodation recess is formed in a bottom surface of the lower case, and a metal plate is fixed to the accommodate recess. Conduction pillars that are formed from a conductive material and that protrude into the housing by penetrating through the lower case are formed on the metal plate. A lower board is electrically, physically connected to the conduction pillars. The upper board is electrically, physically connected to the lower board fixed to the conduction pillars by way of a connecting fitting formed from a conductive material.

### PRIORITY INFORMATION

This application claims priority to Japanese Patent Application No. 2007-025260 filed on Feb. 5, 2007 which is incorporated herein by reference in its entirety.

### BACKGROUND

1. Technical Field

The present invention relates to electronic equipment with a circuit board disposed in a housing formed from an insulating material, and more particularly, to a technique for ensuring a ground for the circuit board and shielding electromagnetic noise.

2. Related Art

Much of electronic equipment has a circuit board that is disposed in a housing formed from an insulating material, such as a resin, and where a plurality of electronic elements are mounted. In order to ground the circuit board and protect the circuit board from electromagnetic noise or prevent emission of electromagnetic noise from the circuit board, a shielding member formed from a metallic material is often provided in the housing. For instance, 2001-320181 A (a 181 patent application) and 2003-264392 A (a 392 patent application) describe electronic equipment having a circuit board and a shielding member formed from a metallic material to cover the circuit board, both of which are provided in a housing. In the 181 patent application and the 392 patent application, grounding of the circuit board and shielding of electromagnetic noise are realized by means of making an attempt to establish electrical conduction between the shielding member and a ground pattern laid on the circuit board. When the shielding member is placed in the housing, ensuring a given gap between the shielding member and the circuit board is required. The reason for this is that terminals of electronic elements, or the like, protruding from the circuit board are prevented from contacting a shielding member formed from a metallic material.

Incidentally, further miniaturization and a further reduction in the thickness of such electronic component are sought. In order to fulfill such a request for a reduction in thickness of the electronic component, an attempt is made to reduce the thickness of the housing or the gap between the shielding member and the circuit board. However, when the thickness of the housing is reduced, there arises a problem of a reduction in rigidity of the housing. Moreover, when the gap between the shielding member and the circuit board is reduced, there arises a problem of terminals of electronic elements projecting from the rear surface of the circuit board, or the like, contacting the shielding member formed from a metallic material, thereby inducing a short circuit. In short, in the related-art technique, difficulty is encountered in reducing the thickness of electronic component while an attempt is made to ground a circuit board and shield electromagnetic noise.

### SUMMARY OF THE INVENTION

Accordingly, the present embodiment provides electronic equipment whose thickness can be reduced while an attempt is made to ground a circuit board and shield electromagnetic noise.

Electronic equipment of the present invention is electronic equipment having a circuit board placed in a housing formed from an insulating material, the equipment comprising a conductive metal plate fixed to a portion of an exterior surface of the housing; and conduction members that are formed from a conductive material and that protrude from the conductive metal plate into the housing and are electrically connected to an earth pattern of the circuit board.

In a preferred mode, the conduction members possess rigidity that enables supporting of the circuit board, and the circuit board is electrically and mechanically connected to the conduction members, so that grounding is ensured and that position of the circuit board in the housing is fixed. More specifically, the conduction members are pillar members that are formed so as to protrude from the conductive metal plate and have female threads formed in upper surfaces of the pillar members, and the conduction members and the earth pattern of the circuit board are formed from a conductive material and electrically and mechanically connected by means of male threads screwed to the female threads.

In another preferred mode, an accommodation recess for accommodating the conductive metal plate is formed in an exterior surface of the housing, and the conductive metal plate is fixed while being accommodated in the accommodation recess. Moreover, it is also preferred that the electronic equipment further comprises a rubber sheet that covers an externally-exposed surface of the conductive metal plate fixed to the housing. In this case, the rubber sheet is preferably formed from conductive rubber possessing conductivity.

In a case where the circuit board is provided in numbers, it is preferred that the electronic equipment further comprises a connecting fitting that is formed from a conductive material and that electrically connects the plurality of circuit boards to respective earth patterns. In this case, it is preferred that the connecting fitting possesses rigidity which enables supporting of the circuit boards and that the circuit board connected to the connecting fitting is electrically and mechanically connected to the other circuit board by way of the connecting fitting, thereby ensuring grounding of the circuit boards and fixing position of the circuit boards in the housing.

According to the present invention, the conductive metal plate acting as a shield member and the earth member is fixed to the exterior surface of the housing. Consequently, even when the housing is slimmed down, rigidity can be ensured. Further, since a housing formed from an insulating material is interposed between the conductive metal plate and the earth pattern, the amount of gap between the conductive metal plate and the circuit board can be reduced. Therefore, the electronic equipment can be slimmed down while an attempt is made to ground the circuit board and shield electromagnetic noise.

The invention will be more clearly comprehended by reference to the embodiment provided below. However, the scope of the invention is not limited to that embodiment.

### BRIEF DESCRIPTION OF THE DRAWINGS

A preferred embodiment of the present invention will be described in detail by reference to the following figures, wherein:

FIG. 1 is a top view and a rear view of a controller for use with an acoustic device which is an embodiment of the present invention;

FIG. 2 is a cross-sectional view taken along line A-A shown in FIG. 1;

FIG. 3 is a top view of an upper case and a cross-sectional view of the same taken along line B-B;

FIG. 4 is a top view of a lower case and a cross-sectional view of the same taken along line C-C;

FIG. 5 is a top view of a metal plate and a cross-sectional view of the same taken along line D-D; and

FIG. 6A and FIG. 6B are perspective views of two types of connecting fitting.

### DETAILED DESCRIPTION

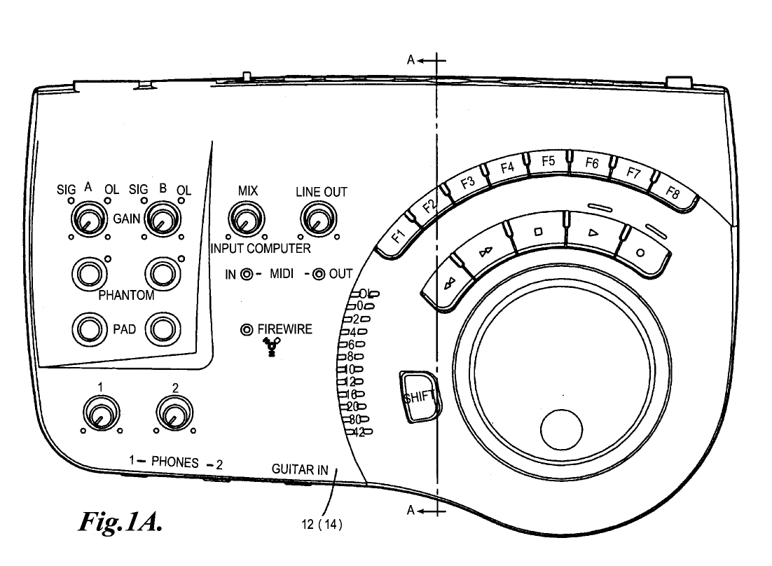

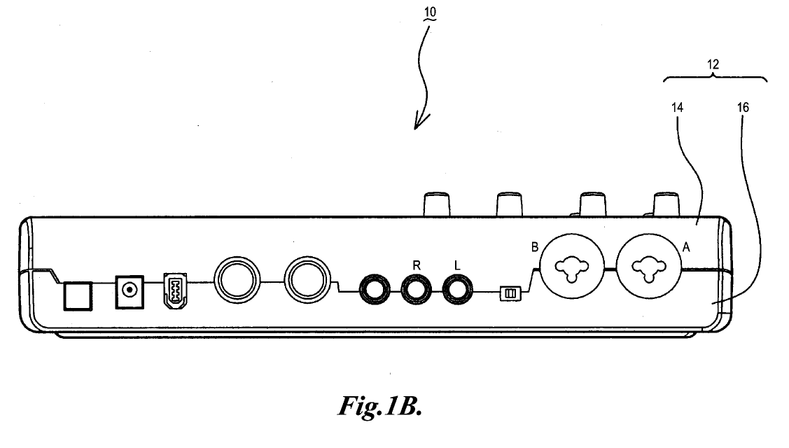

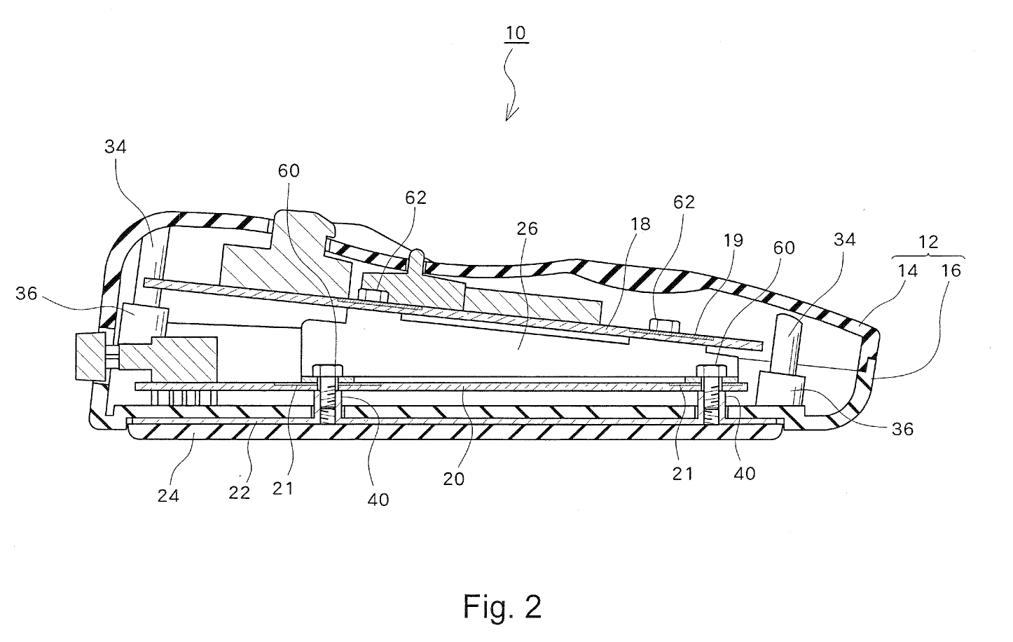

An embodiment of the present invention will be described hereunder by reference to the drawings. FIG. 1 is a top view and a rearview of a controller 10 for use with an acoustic device that is an embodiment of the present invention. Moreover, FIG. 2 is a cross-sectional view taken along line A-A shown in FIG. 1.

The controller 10 is electronic equipment that is connected to an acoustic device (not shown) by way of a cable and that receives an operation command pertaining to the acoustic device from a user. A housing 12 of the controller 10 is made up of an upper case 14 and a lower case 16 which are fitted together. Two circuit boards; namely, an upper board 18 and a lower board 20, are placed in a stacked manner within the housing 12 made up of the cases 14 and 16. The lower substrate 20 of the boards is fixed to conduction pillars 40 that are fixed to a bottom surface of the housing 12 and that are formed so as to protrude from a metal plate 22. The upper board 18 is fixedly disposed with respect to the lower board 20 fixed to the conduction pillars 40 by way of a connecting fitting 26. At this time, the boards 18 and 20 are electrically connected to the metal plate 22 by way of the conduction pillars 40 and the connecting fitting 26, or the like, whereby grounding of the boards 18 and 20 is ensured. The configuration of the controller 10 will be described in detail.

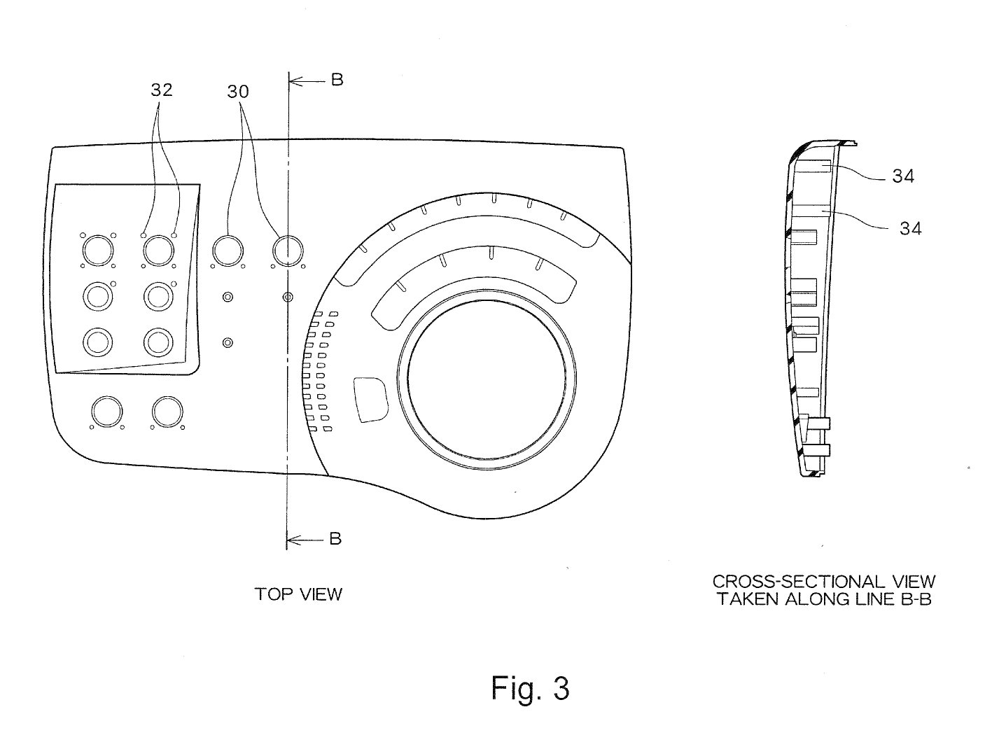

As mentioned previously, the housing 12 of the controller 10 is made up of the upper case 14 and the lower case 16 that are fitted together. FIG. 3 is a top view of the upper case 14 and a cross-sectional view of the same taken along line B-B. The upper case 14 is a member that is formed from resin corresponding to an insulating material and that assumes essentially the shape of a dish. A switch hole 30 for allowing passage of a head of a switching element provided on the upper board 18 and a guide light hole 32 for guiding to the outside light from an LED, or the like, placed on the upper board 18 are provided in numbers on an upper surface of the upper case 14. Moreover, upper pillars 34 extending toward the lower case 16 are formed protrusively on the rear surface (inner surface) of the upper case 14.

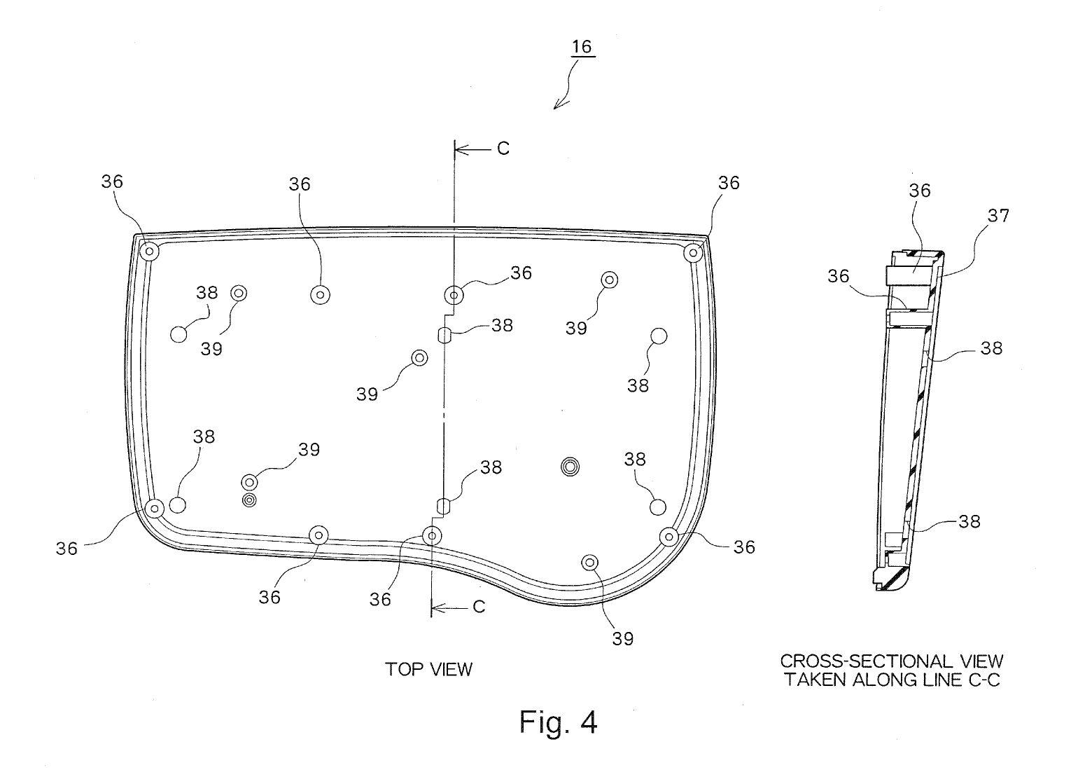

FIG. 4 is a top view of the lower case 16 and a cross-sectional view of the same taken along line C-C. The lower case 16 is also a member that is formed from resin corresponding to an insulating material and that assumes essentially the dish-shaped form conforming to the upper case 14. Lower pillars 36 extending toward the upper pillars 34 are formed at positions on the lower case 16 corresponding to the upper pillars 34. When the cases 14 and 16 are assembled, the lower pillars 36 contact the upper pillars 34 of the upper case 14.

An accommodation recess 37 for accommodating the metal plate 22 and a rubber sheet 24 is formed in the bottom surface of the lower case 16. The accommodation recess 37 has a peripheral shape conforming to the metal plate 22 and the rubber sheet 24, and the depth of the accommodation recess 37 is slightly larger than the thickness of the metal plate 22. Therefore, the metal plate 22 and the rubber sheet 24 accommodated in the accommodation recess 37 are positioned by means of an outer edge of the accommodation recess 37.

The metal plate 22 accommodated in the accommodation recess 37 is connected to the lower case 16 through screw engagement by means of metal plate mount bolts (not shown). Therefore, a plurality of metal plate mount holes 39 into which male thread sections of the metal plate mount bolts are inserted are formed in the lower case 16. As will be described in detail later, the conduction pillars 40 are formed in a protruding manner on the metal plate 22. Conduction pillar passage holes 38 are also formed in the lower case 16 in order to allow extension of the conduction pillars 40 into the housing 12.

As shown in FIG. 2, the upper board 18 and the lower board 20 are stacked into layers within the housing 12 consisting of the upper case 14 and the lower case 16. Both the upper board 18 and the lower board 20 correspond to a circuit board on which a plurality of electronic elements are arranged. Respective earth patterns 19 and 21 formed by application of a conductive material (metal or the like) are provided in numbers at predetermined positions on the respective boards 18 and 20. Grounding of the boards 18 and 20 is ensured by electrical connection of the earth patterns 19 and 21 to some type of an earth member. In the present embodiment, in order to ensure grounding and fix the positions of the respective boards 18 and 20, through holes (not shown) are formed in essentially the centers of the respective earth patterns 19 and 21. By use of fastening bolts 60 and 62 inserted into the through holes, the respective board 18 and 20 are fastened to the conduction pillars 40 or the connecting fitting 26, thereby fixing the positions of the respective boards 18 and 20 and ensuring grounding of the same. This will be described in detail later.

Incidentally, in the present embodiment, the upper board 18 is tilted with respect to the lower board 20. Specifically, the controller 10 of the present embodiment assumes a shape whose upper surface is tilted with respect to a bottom surface. The upper board 18 is arranged essentially in parallel with the upper surface of the controller 10, and the lower board 20 is arranged essentially in parallel with the bottom surface of the controller 10. Legs (terminals which are not shown) of electronic elements mounted on the boards 18 and 20 protrude from the bottom surfaces of the respective boards 18 and 20. The respective boards 18 and 20 are arranged while being kept apart from each other by a distance which hinders the legs of the electronic elements from interfering with other members provided on lower sides of the boards 18 and 20 (i.e., the lower board 20 from interfering with the upper board 18 and the lower case 16 from interfering with the lower board 20).

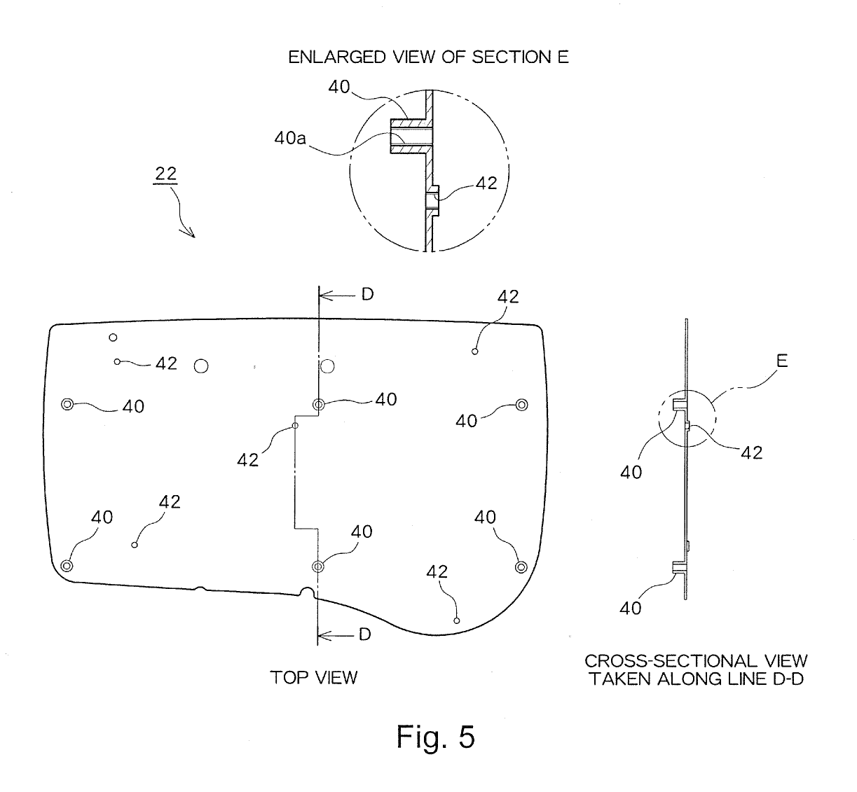

Next, the metal plate 22 will be described. FIG. 5 is a top view of the metal plate 22 and a cross-sectional view of the same taken along line D-D. The metal plate 22 is a plate material formed from a conductive material. The metal plate 22 is screw-fastened to the bottom surface of the lower case 16 by means of metal plate mount bolts (not shown) inserted from the inside of the housing 12. Therefore, metal plate mount female threads 42 to which the metal plate mount bolts are screwed are formed at predetermined positions on the metal plate 22.

As mentioned previously, the conduction pillar 40 extending to the inside of the housing 12 by penetrating through the lower case 16 is formed in numbers on the metal plate 22. The conduction pillars 40 are formed from the same conductive material as that of the metal plate 22. A conduction female thread 40a is formed on the upper surface of each conduction pillar 40, and the lower fastening bolts 60 (see FIG. 2) for screw-fastening the lower board 20 are screwed into the conduction female threads 40a. The plurality of conduction pillars 40 are formed at positions corresponding to the fastening holes formed in the lower board 20.

When the position of the lower board 20 is fixed, the lower board 20 is placed in such a way that the fastening holes of the lower board 20 are overlaid on the plurality of conduction pillars 40. The lower board 20 is fastened, in this state, to the conduction pillars 40 by means of the lower fastening bolts 60 formed from a conductive material. As a result, the lower board 20 is fixed to the conduction pillars 40, whereby the position of the lower board 20 is fixed. Specifically, the metal plate 22 including the conduction pillars 40 acts as a fixing member that fixes the position of the lower board 20. In the present embodiment, the connecting fitting 26 is also fastened to the conduction pillars 40 along with the lower board 20 by means of the lower fastening bolts 60.

Both the lower fastening bolts 60 and the connecting fitting 26 are formed from a conductive material. Therefore, the earth pattern 21 on the lower board 20 is electrically connected to the metal plate 22 by way of the connecting fitting 26, the lower fastening bolts 60, and the conduction pillars 40. Grounding of the lower board 20 is ensured by means of electrical connection. Namely, the metal plate 22 acts also as an earth member for ensuring grounding of the lower board 20.

The metal plate 22 fixed to the bottom surface of the housing 12 completely covers the single side of the circuit board 18 and that of the circuit board 20. Both electromagnetic noise emitted from the circuit boards 18 and 20 and electromagnetic noise traveling from the outside toward the circuit boards 18 and 20 are shielded by means of the metal plate 22 covering the single sides of the respective circuit boards 18 and 20. In the present embodiment, the metal plate 22 acts also as a shield member for shielding electromagnetic noise.

A rubber sheet 24 is fixed to the bottom surface of the metal plate 22 (see FIG. 2). The rubber sheet 24 is a sheet-like member formed from rubber. The rubber sheet 24 assumes a shape conforming to the metal plate 22 and can fully cover the metal plate 22. As a result of the metal plate 22 being covered with the rubber sheet 24, slippage of the controller 10 is reduced, and the design of the controller is enhanced. Although the rubber sheet 24 is formed from ordinary rubber (an elastic material) in the present embodiment, the rubber sheet may also be formed from conductive rubber exhibiting conductivity. The rubber sheet 24 can also act as a shield member for shielding electromagnetic noise by means of forming the material of the rubber sheet 24 from conductive rubber, whereby the electromagnetic noise shielding effect can be enhanced to a much greater extent.

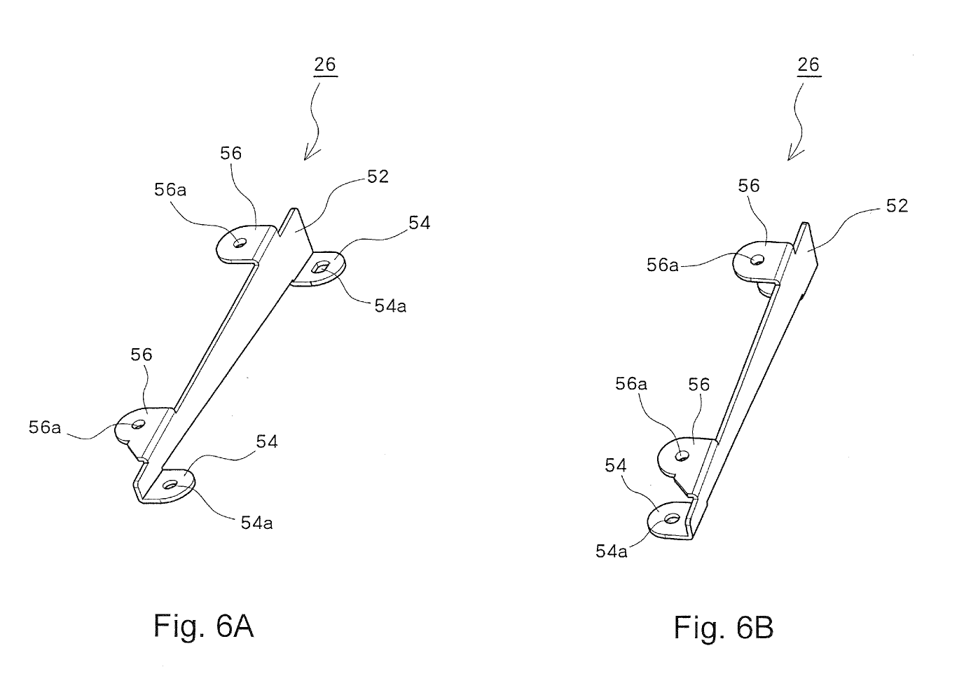

Next, the connecting fitting 26 for coupling the lower board 20 to the upper board 18 will be described. FIGS. 6A and 6B are perspective views of two types of connecting fittings 26. The connecting fitting 26 is a sheet metal member formed from a conductive material. The shape of the connecting fitting 26 is formed by bending four small pieces 54 and 56, which extend from neighborhoods of the four corners of a flat base section 52, into about a 90° angle with respect to the base section 52. As shown in FIGS. 6A and 6B, all of the small pieces 54 and 56 may be bent in the same direction or in different directions.

Of the four small pieces 54 and 56, the two small pieces 54 extending from the lower end of the base section 52 serve as lower connection sections 54 connected to the lower board 20. Further, the two small pieces 56 extending from the upper end of the base section 52 serve as upper connection sections 56 connected to the upper board 18. The amount of gap between the upper board 18 and the lower board 20 is regulated by the height of the base section 52 that connects together the lower connection sections 54 and the upper connection sections 56. In the present embodiment, the upper board 18 is tilted with respect to the lower board 20, and the amount of gap between the boards gradually changes. Therefore, the base section 52 also assumes a shape whose height gradually changes.

Lower board penetration holes 54a into which the previously-described lower fastening bolts 60 are inserted are formed in the lower connection sections 54. The lower connection sections 54 are screw-fastened to the conduction pillars 40 along with the lower board 20 by means of the lower fastening bolts 60, whereby the connecting fitting 26 is positionally fixed with respect to the lower board 20.

Moreover, upper board female threads 56a into which the upper fastening bolts 62 (see FIG. 2) formed from a conductive material are screwed are formed in the upper connection sections 56. The upper fastening bolts 62 pass through conduction holes of the upper board 18, to thus be screwed to the upper board female threads 56a. As a result, the upper board 18 is screw-fastened to the connecting fitting 26. At this time, the upper connection sections 56 are electrically connected to the earth pattern 19 on the upper board 18 by way of the upper fastening bolts 62 formed from a conductive material. As mentioned previously, the earth pattern 21 of the lower board 20 is electrically connected to the metal plate 22 fixed to the bottom surface of the housing 12 by way of the lower fastening bolts 60 and the conduction pillars 40. Therefore, as a matter of course, the earth pattern 19 of the upper board 18 is electrically connected to the metal plate 22 by way of the earth pattern 21 of the lower board 20.

As is obvious from the above descriptions, in the present embodiment, fixing of the positions of the two circuit boards 18 and 20 and electrical connection of the earth patterns 19 and 21 of the boards 18 and 20 to the metal plate 22 are achieved by means of the connecting fitting 26, the fastening bolts 60 and 62, and the conduction pillars 40. Moreover, the metal plate 22 blocks the boards 18 and 20 from electromagnetic noise.

Incidentally, as is evident from the above descriptions, the metal plate 22 is placed on the bottom surface of the lower case 16; in other words, outside the housing 12 (see FIG. 2), in the embodiment. This is intended to enable a further reduction in the thickness of the controller 10 while ensuring grounding of the circuit board 18 and 20 and shielding of electromagnetic noise.

Specifically, in many related-art electronic devices having shield members such as metal plates, the shield member has hitherto been placed in the housing 12. However, in this case, sufficient gap must be ensured between the shield member and the circuit board, which poses difficulty in reducing the thickness of the device. For instance, in the present embodiment, it is assumed that the metal plate 22 is placed in the housing 12; specifically, that the metal plate 22 is attached to the upper surface of the lower case 16 rather than to the bottom surface of the same. In this case, an insulation member is not present between the metal plate 22 and the lower board 20. Therefore, legs (terminals) of electronic elements protruding from the rear surface of the lower board 20 may contact the metal plate 22, which in turn raises a problem of occurrence of a short circuit or the like. In order to prevent occurrence of such a problem, a gap of sufficient size must be ensured between the lower board 20 and the metal plate 22. In particular, in the case of a device in which user's force exerted during operation of a switch acts on the boards 18 and 20 as in the controller 10, there are cases where the boards 18 and 20 are deflected by the force exerted during operation of the switch. Therefore, a large gap taking into account the amount of deflection must be ensured between the lower board 20 and the metal plate 22. However, as a matter of course, ensuring such a gap leads to an increase in the thickness of the entire controller 10.

For this reason, in the present embodiment, the metal plate 22 is placed outside the housing 12. In this case, the lower case 16 acting as an insulating material is interposed between the metal plate 22 and the lower board 20. Consequently, even when a gap between the lower board 20 and the metal plate 22 (i.e., a gap between the board and the lower cover) is small, there is no fear of the legs of the electronic elements electrically contacting the metal plate 22. In short, a significant reduction in the gap between the lower board 20 and the metal plate 22 is enabled by means of attaching the metal plate 22 to the outside of the housing 12, and the entirety of the controller 10 can be slimmed down while grounding and shielding of electromagnetic noise are ensured.

Moreover, in the present embodiment, the rigidity of the housing 12 is enhanced by fixing the metal plate 22 to the bottom surface of the lower case 16. Specifically, in order to slim down the controller 10, a reduction in the thickness of the housing 12 is also required. However, when the housing 12 formed basically from a resin of low stiffness is slimmed down, there arises a problem of a significant reduction arising in the rigidity of the entire housing 12. However, as in the case of the present embodiment, the metal plate 22 formed from a metal material of high stiffness is fixed to the bottom surface of the housing 12, whereby sufficient rigidity can be ensured when the thickness of the housing 12 is reduced. Namely, besides acting as the earth member, the shield member, and the fixing member for fixing the position of the lower board 20, the metal plate 22 acts also as a reinforcing member for reinforcing the rigidity of the housing 12 in the present embodiment.

Next, operation for assembling the controller 10 will be briefly described. When the controller 10 is assembled, the metal plate 22 and the rubber sheet 24 are previously fixed to the bottom surface of the lower case 16, thereby causing the conduction pillars 40 to penetrate through the lower case 16.

The lower board 20 on which predetermined electronic elements are arranges is placed on the plurality of conduction pillars 40 penetrated through the lower case 16. At this time, the conduction holes formed in essentially the center of the earth pattern 21 of the lower board 20 are positioned immediately above the conduction female threads 40a formed in the conduction pillars 40. The connecting fittings 26 are placed on the lower board 20 positioned on the conduction pillars 40. At this time, the lower board penetration holes 54a of the connecting fitting 26 are positioned immediately above the conduction holes of the lower board 20. The lower fastening bolts 60 formed from a metal material are inserted into the lower board through holes 54a and the conduction holes from the above and are screwed to the conduction female threads 40a. As a result, the lower board 20 and the connecting fitting 26 are fixed to the conduction pillars 40. Further, the earth pattern 21 of the lower board 20 is electrically connected to the metal plate 22 by way of the conduction pillars 40 or the like, whereby grounding of the lower board 20 is ensured.

Subsequently, the upper board 18 is placed on the upper connection sections 56 of the connecting fitting 26 screw-fastened to the lower board 20. At this time, the conduction holes formed in essentially the center of the earth pattern 19 of the upper board 18 are positioned immediately above the upper board female threads 56a formed in the connecting fitting 26. The upper fastening bolts 62 formed from a metal material are inserted into the conduction holes from above and screwed to the upper board female threads 56a. As a result, the upper board 18 is fixed to the connecting fitting 26. The earth pattern 19 of the upper board 18 is electrically connected to the metal plate 22 by way of the connecting fitting 26 and the earth pattern 19 of the lower board 20, thereby ensuring grounding of the upper board 18.

After the lower board 20 and the upper board 18 have been positionally fixed, the upper case 14 is put on the lower case 16 from above, and the cases are fitted together. Finally, switch elements protruding from switch holes 30 of the upper case 14 are covered with a predetermined switch cover, whereupon assembly of the controller 10 is completed.

As is obvious from the above descriptions, the controller is assembled in the present embodiment by means of placing members in sequence from below; namely, in sequence of the lower case 16, the lower board 20, the upper board 18, and the upper case 14, and the thus-placed members are fixed together. Therefore, the controller 10 does not need to be inverted in the middle of assembly operation, and hence the controller can be assembled readily. Further, in the present embodiment, fixing the positions of the boards 18 and 20 and ensuring grounding of the boards are performed simultaneously, and hence a reduction in the number of parts and more efficient assembly can be performed.

In the present embodiment, an explanation is provided by means of taking, as an example, an electronic device including two circuit boards, but the number of circuit boards may also be one. Moreover, even an electronic device including three or more circuit boards can also be addressed by means of increasing the number of connecting fittings. The shapes of the metal plate, the conduction pillars, and the connecting fitting provided in the above descriptions are mere examples, and other shapes may naturally be assumed, so long as the metal plate is fixed to an exterior surface of the housing.

What is claimed is:

1. Electronic equipment having a circuit board placed in a housing formed from an insulating material, the equipment comprising:
a conductive metal plate fixed to a portion of an exterior surface of the housing; and
conduction members that are formed from a conductive material and that protrude from the conductive metal plate into the housing and are electrically connected to an earth pattern of the circuit board.

2. The electronic equipment according to claim 1, wherein the conduction members possess rigidity that enables supporting of the circuit board, and the circuit board is electrically and mechanically connected to the conduction members, so that grounding is ensured and that position of the circuit board in the housing is fixed.

3. The electronic equipment according to claim 2, wherein the conduction members are pillar members that are formed so as to protrude from the conductive metal plate and have female threads formed in upper surfaces of the pillar members, and the conduction members and the earth pattern of the circuit board are formed from a conductive material and electrically and mechanically connected by means of male threads screwed to the female threads.

4. The electronic equipment according to claim 1, wherein an accommodation recess for accommodating the conductive metal plate is formed in an exterior surface of the housing, and the conductive metal plate is fixed while being accommodated in the accommodation recess.

5. The electronic equipment according to claim 1, further comprising a rubber sheet that covers an externally-exposed surface of the conductive metal plate fixed to the housing.

6. The electronic equipment according to claim 5, wherein the rubber sheet is formed from conductive rubber possessing conductivity.

7. The electronic equipment according to claim 1, further comprising, in a case where the circuit board is provided in numbers, a connecting fitting that is formed from a conductive material and that electrically connects the plurality of circuit boards to respective earth patterns.

8. The electronic equipment according to claim 7, wherein the connecting fitting possesses rigidity which enables supporting of the circuit boards, and the circuit board connected to the connecting fitting is electrically and mechanically connected to the other circuit board by way of the connecting fitting, thereby ensuring grounding of the circuit boards and fixing position of the circuit boards in the housing.
